(19) United States
(12) Patent Application Publication
(10) Pub. No.: US 2003/0080757 A1
(43) Pub. Date: May 1, 2003

(54) Proximity sensor

(76) Inventors: Thomas A. Groover, Houston, TX (US); King L. Poon, Missouri City, TX (US)

Correspondence Address: ROSENTHAL & OSHA L.L.P., Suite 2800, 1221 McKinney St., Houston, TX, 77010, US

(21) Appl. No.: 10/284,628

(22) Filed: Oct. 31, 2002

Related U.S. Application Data
(60) Provisional application No. 60/335,982, filed on Nov. 1, 2001.

(51) Int. Cl. G01R 27/26

(52) U.S. Cl. 324/662

(57) ABSTRACT

In one embodiment, a proximity sensor is disclosed. The proximity sensor is adapted for use in a housing, such as an explosion-proof housing, and includes a compressible sensor plate and an interface board. The sensor plate is compressed during assembly of the housing. The proximity sensor interacts with other electrical components within and external to the housing. Furthermore, the proximity sensor may include, or interact with, a display. Components, including the proximity sensor, may be configured for use in a hazardous environment and designed to draw minimal current.

### CROSS-REFERENCE TO RELATED APPLICATIONS

This application claims the benefit of, and incorporates by reference in its entirety, Provisional Application No. 60/335,982, filed on Nov. 1, 2001.

### BACKGROUND OF INVENTION

1. Field of the Invention

The present invention relates generally to communication and control systems for use in monitoring and controlling various systems and equipment in industrial environments.

2. Background Art

At locations where oil or gas wells are being drilled, a number of flammable gases may be present, including mixtures of oxygen, methane, ethane, propane, hydrogen sulfide and others. Similar potentially dangerous environmental conditions exist in locations in which petroleum products are being recovered, refined or processed. Likewise, in industrial areas where large quantities of dust are present, such as in grain handling facilities or pulp and paper mills, hazardous environmental conditions may exist. Standardized classifications for the various types of hazardous locations have been adopted and assigned by regulatory agencies according to the nature and type of hazard that is generally present or that may occasionally be present.

Because electrical components, by their nature, may generate heat and sparks sufficient to ignite a flammable gas or other flammable mixture under even normal operating conditions, such components must be carefully selected and installed when used in an area that is classified as hazardous. More specifically, the components must exceed certain minimum standards as to such characteristics as power consumption, operating temperature, current and voltage requirements, and energy storage capabilities. These standards are also established by regulatory authorities and vary depending upon the particular hazardous environment.

Certain electrical devices are intrinsically safe. An intrinsically safe device may be generally described as a device that during normal operation, as well as operation during any fault condition, cannot cause a spark or achieve a temperature sufficient to ignite the gas or other substance that is present and that causes the area to be classified. If a device is not intrinsically safe, other means must be provided to ensure that the device cannot serve as a source of ignition. Typically where a device is not intrinsically safe, it may be made safe by housing it in an explosion proof enclosure. An explosion proof box or enclosure, as that term is used herein, means an enclosure that prevents any explosion within the enclosure from causing the atmosphere outside the box to ignite.

Although areas that are classified as hazardous are prevalent in many industries, the problems of powering and communicating with electrical devices in hazardous areas are particularly acute in the production, gathering, distribution and transportation of oil and gas. For instance, in drilling a well, a great deal of equipment is located in close proximity to the well head, including mud pumps, compressors, mud pits and other subsystems associated with drilling, Many of these areas around a drilling site are classified as hazardous, and thus special precautions are required with respect to the electrical communication and power distribution systems. To efficiently and safely control the drilling operation, the driller will require a system having sensors positioned in a number of locations in the hazardous area. These sensors will transmit needed data to a computer which can process that data and transmit important information to the driller by means of a console or monitor. By viewing the information on the monitor, the driller can then make whatever changes are appropriate to the system to assure safe and efficient operation.

The monitor is typically required to be very close to the well head and thus is located in a hazardous area. Historically, such consoles have varied with respect to the amount of information displayed and type of indicators used. In the past, when a simple meter or gage provided all the information that was required, the device could sometimes be made intrinsically safe. However, due to the sophistication of today's drilling practices, consoles or monitors usually must provide a driller with a tremendous amount of information concerning the location and orientation of the drill bit, the mud flow rates, downhole pressures, gas flow, as well as the status of the other systems supporting the drilling operation. Additionally, the console may permit the driller to issue commands or make inquiries through the use of a keyboard or key pad, and must display all the needed information by means of an LCD or other display. These modern consoles or monitors typically have a substantial power requirement that has prevented them from being made intrinsically safe, and often requires that they be housed in an explosion proof enclosure.

Because drilling consoles and monitors are often located in areas where running power lines is difficult, it is often desirable to equip such units with an internal power source, such as a battery, that can be safely located within the explosion-proof housing. Often, such internal power sources are used in conjunction with a solar power source in order to provide power when sufficient solar power cannot be produced, and to supplement the power provided by solar power units. Because the amount and consistency of solar power will vary, it would be advantageous to develop low power consumption components for these units, in order maximize the amount of run time during periods in which solar power is unavailable.

Another approach to increasing the working life of a power source is to shut down non-essential functions when not in use, and run components only to the extent necessary to perform desired functions (e.g. running a microprocessor at a lower clock speed). However, this task is made difficult in a hazardous area because methods of regulating power to the system, and configuring operating ranges of components, are limited. For instance, a typical toggle switch cannot be used in such an area, due to its electrical characteristics. Therefore, it would be advantageous to develop a power control system that may be used safely in a hazardous area, so that electrical components (e.g., a visual display, microprocessor, or infrared data link) can be regulated to consume minimal power. This avoids unnecessary consumption of power.

Furthermore, because of the hazardous environment in which such equipment is used, it is advantageous to minimize the number and complexity of the components, thereby minimizing the need to open the enclosure for repair or replacement of components. Other complications associated with opening the enclosure include the need to lubricate threads and O-rings to prevent galling, and the possibility that dust and particles in the air may damage the threads during reassembly. Thus, it is advantageous to develop a system that minimizes the need to open such an enclosure in a hazardous area.

### SUMMARY OF INVENTION

In one embodiment, the present invention is a proximity sensor particularly adapted for use in hazardous environments and in the housings commonly used in such environments, such as explosion-proof housings. The proximity sensor includes a sensor plate and interface board. The proximity sensor may be disposed within a housing so that the sensor plate is proximal to, or touches, an external member of the housing, thereby increasing the sensitivity of the proximity sensor. Furthermore, the location of the proximity sensor near an external member will require less current while maintaining a desired detection sensitivity.

In one embodiment, the present invention is a sealed housing for use in hazardous or harsh environments and equipped with a proximity sensor. The housing may include a window or transparent member for use with the proximity sensor and for viewing a display disposed within the housing. The display may be integrated into an interface board of the proximity sensor. Alternatively, the interface board may include a window for viewing a display mounted proximal to the interface board.

Other aspects and advantages of the invention will be apparent from the following description and the appended claims.

### BRIEF DESCRIPTION OF DRAWINGS

FIG. 1 shows one embodiment of an explosion-proof module with proximity sensor.

FIG. 2 shows a sensor plate mounted on an interface board, according to one embodiment of the invention.

FIG. 3 demonstrates the disposition of a proximity sensor within a front housing cover, according to one embodiment of the invention.

FIG. 4 is a side view of a sensor plate according to one embodiment of the invention.

FIG. 5 is a bottom view of a sensor plate according to one embodiment of the invention.

### DETAILED DESCRIPTION

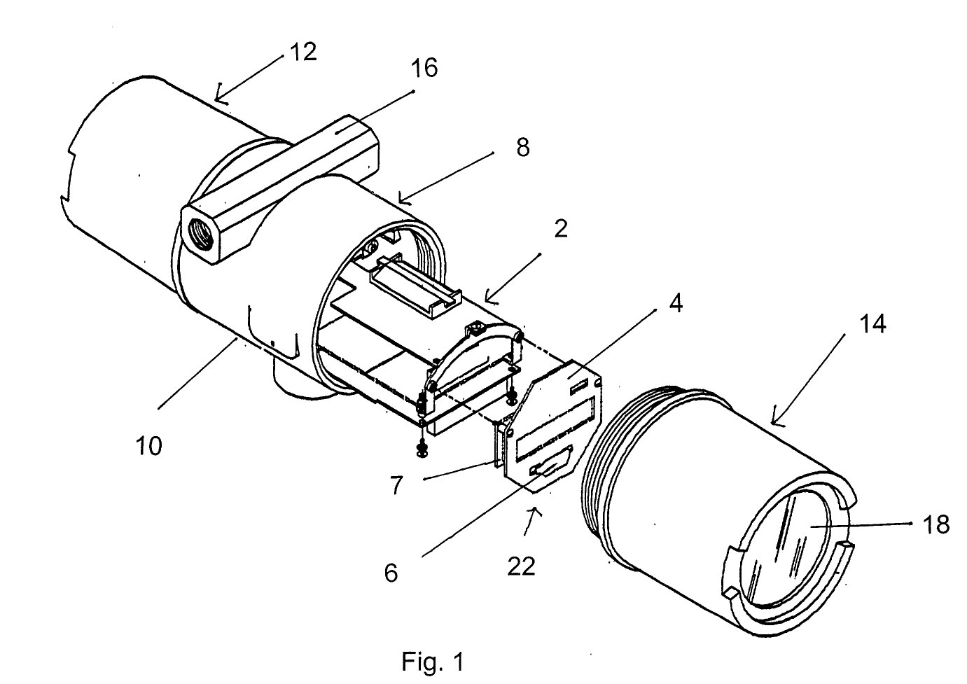

The invention relates to proximity sensors that can be used in a hazardous environment and have extremely low power consumption (e.g., a few milliwatts). FIG. 1 is a partial schematic view of sealable module (“module”) according to one embodiment of the invention. The module includes a proximity sensor 22 comprising an interface board 4 and sensor plate 6. The proximity sensor 22 may be of any type known in the art, including, but not limited to, capacitive and resistive proximity sensors. A housing 8 may consist of a single member or may comprise any number of separate external members. In one embodiment, these external members include a mounting cover 10, rear housing cover 12, and front housing cover 14. An external member may include one or more interfaces for connecting external components, or for the ingress or egress of various conduits including, but not limited to, cables and hoses. Such interfaces may be configured to accommodate various components or conduits. For instance, the embodiment shown in FIG. 1 includes an antenna interface 16. The antenna interface 16 may include threads, to accommodate a threaded antenna component (not shown). Because of the desire to use various components with the module, based on a particular job, location, or other parameters, it should be understood that interfaces may vary widely both in configuration, and location on the module. Furthermore, in one or more embodiments, the module may be explosion proof.

The external members of the housing 8 may be connected in any fashion known in the art to meet applicable standards for the environment in which the module will be used. In one embodiment, assembly of the housing 8 may be performed without any special tools or devices, through the use of mating threads on the external members, or other fastening devices known in the art. Furthermore, in one embodiment the housing 8 may include one or more transparent members 18. The transparent member 18 may comprise any suitable material known in the art, including, but not limited to, glass and plastic. In one embodiment, the entire housing 8, or an external member of the housing 8 may comprise a transparent material.

Referring again to FIG. 1, electrical components 2 are disposed within the housing 8. The nature and configuration of the electrical components 2 will vary widely based on the purpose of the particular module and other considerations, and may include any suitable electrical components known in the art. In one embodiment, such electrical components 2 may comprise a measurement computer. In the embodiment shown, electrical components 2 may include one or more displays 7.

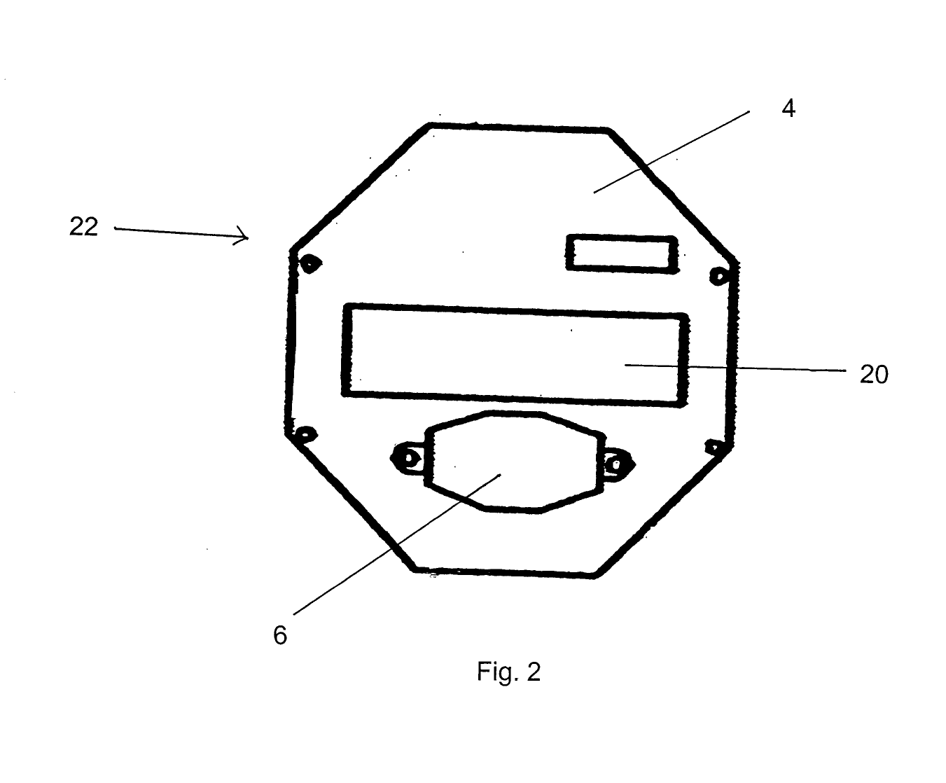

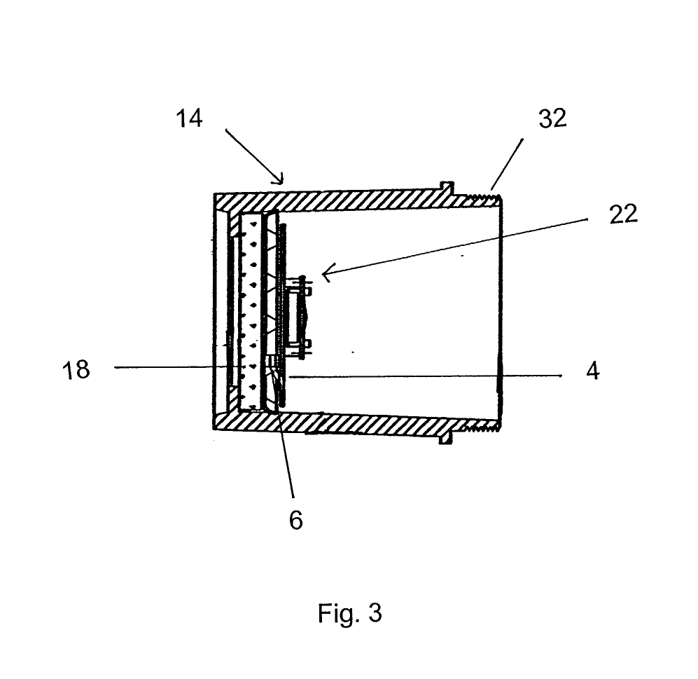

One or more proximity sensors 22 are disposed within the housing 8 and operatively connected to the electrical components 2. Referring to the embodiment of FIG. 2, a proximity sensor 22 includes an interface board 4 and sensor plate 6. The sensor plate 6 is operatively connected to the interface board 4 such that the sensor plate 6 will be proximate an external member of the housing 8. Referring to the embodiment of FIG. 3, the sensor plate is proximate a transparent member 18. In one embodiment, the sensor plate 6 is in contact with a transparent member 18. In one embodiment, the sensor plate 6 is compressed by the transparent member 18.

Because the external members of the housing 8 may interconnect in various ways, it is advantageous to provide a proximity sensor 22 having a sensitivity that will not be diminished by various methods of interconnection. Particularly, in embodiments where the sensor plate 6 may contact the transparent member 18, or is compressed by the transparent member 18, it is desirable that the sensitivity of the sensor plate 6 is not diminished by deformation or other effects of the movement of the transparent member 18.

FIG. 2 illustrates an interface board 4, according to one embodiment of the invention. A window 20 may be provided in the interface board 4 to permit viewing of data on a display 7 (not shown in FIG. 2) located behind the interface board 4. Alternatively, a display 7 may be integrated into the interface board 4. The sensor plate 6 is operatively connected to the interface board 4 such that it does not obscure the window 20, or extend beyond the periphery of the interface board 4, or contact any part of the housing 8 (shown in FIG. 1).

FIG. 3 demonstrates the position of the interface board 4, and sensor plate 6, within an external member of the housing 8, according to one embodiment. In this embodiment, the proximity sensor 22 is located within the front housing cover 14 of the housing 8. The proximity sensor 22 is positioned proximal a transparent member 18, such that the sensor plate 6 is in close proximity to, or in contact with, the transparent member 18. The proximity sensor 22 is operatively connected to one or more electrical components 2 (shown in FIG. 1). During assembly or reassembly of the module, the front housing cover 14 will be fastened to an external member of the housing 8 (shown in FIG. 1), by threads 32, or other fasteners known in the art. As the front housing cover 14 comes to rest, the transparent member 18 of the front housing cover 14 will be in close proximity to the sensor plate 6. In one embodiment, fastening of the front housing cover 14 will cause compression of the sensor plate 6 of the proximity sensor 22.

Compression of the sensor plate 6 will increase the sensitivity of the proximity sensor 22 by increasing the contact area with the transparent member 18 and decreasing the distance between the sensor plate 6 and an external trigger (e.g. an operator's finger). Furthermore, the increased contact area and decreased distance achieved by compression of the sensor plate 6 will decrease the current required to operate the proximity sensor 22 at a desired sensitivity.

Alternatively, the proximity sensor 22 may be located anywhere within the housing 8. In one embodiment, multiple proximity sensors 22 may be included in the module. In another embodiment, multiple sensor plates 6 may operatively connect to a single interface board 4. Where multiple sensor plates 6 or multiple proximity sensors 22 are used, more advanced interaction with the electrical components 2 of the module is possible. For instance, the use of multiple sensor plates 6 or proximity sensors 22 may provide the functionality and interaction of a keyboard, mouse, or any other input device known in the art.

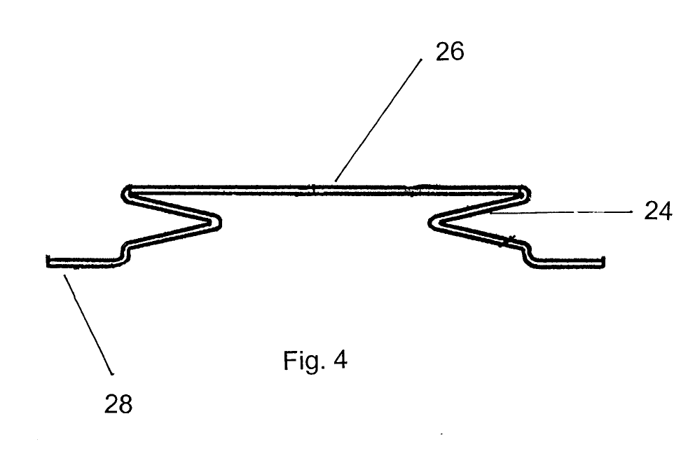

FIG. 4 is a side view of one embodiment of a sensor plate 6. In this embodiment, the sensor plate 6 is a one-piece conductive member. Alternatively, the sensor plate 6 may comprise multiple conductive members. In one or more embodiments, the conductive member comprises a stainless spring steel alloy. In one embodiment, the sensor plate 6 is pressed against the transparent member 18 (see FIG. 3). Accordingly, one or more legs 24 of the sensor plate 6 are non-linear to permit compression. A top surface 26 of the sensor plate 6 may be substantially flat (as shown) or may be curved so that a compression of the sensor plate 6 will decrease the curvature and make tight contact with the transparent member 18. At least one leg 24 terminates in a relatively flat mounting tab 28. The mounting tab 28 can be operatively connected to an interface board 4 (not shown) or other electrical component.

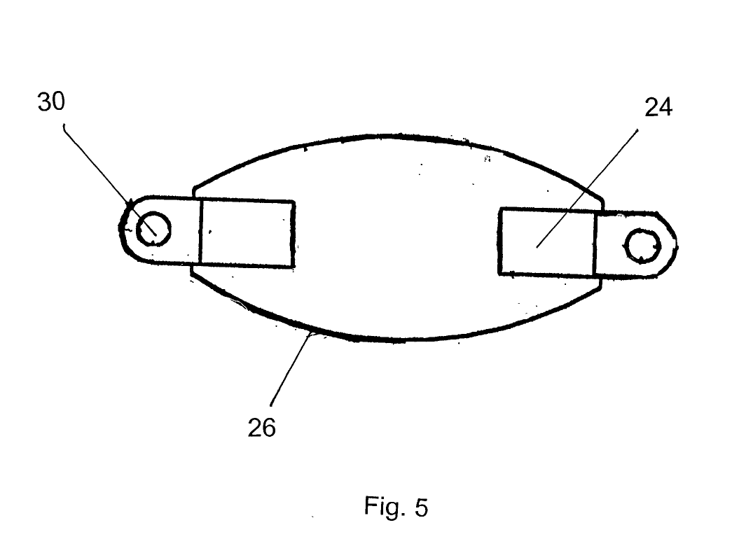

FIG. 5 is a bottom view of a sensor plate 6 according to one embodiment of the invention. The top surface 26 may have curved edges (as shown) or may be of any desired shape. Curved sides are advantageous because they provide increased surface area while minimizing interference with the window 20 (not shown) and preventing contact with the sides of the housing 8 (not shown) or any other electrical components 2 (not shown). The mounting tabs 28 of one or more legs 24 may contain one or more holes 30 for connecting to an interface board 4. However, it is not necessary to use holes 30 for connecting the sensor plate 6 to an interface board 4 or other component. Connections may be of any type known in the art. In one embodiment, at least one connection is conductive.

The structure of the sensor plate 6 advantageously allows it withstand various forces, including compression and twisting forces that may be exerted on the sensor plate 6 during mounting or installation of various external members of the housing 8, and other components, without adversely impacting the functionality of the sensor plate 6. Furthermore, the sensor plate 6 should not bind the external members as they are moved and/or rotated during assembly. Therefore, the relative position of the sensor plate 6 to the transparent member 18 or the window 20 should not be distorted as the module is assembled. The leg 24 has a resistance to significant motion, while providing a spring-type mount. Bowing of the sensor plate 6, that may occur during compression, may advantageously increase the contact between the sensor plate 6 and a compressing member, such as a transparent member 18, thereby increasing sensitivity and/or decreasing power consumption.

While the invention has been described with respect to a limited number of embodiments, those skilled in the art, having benefit of this disclosure, will appreciate that other embodiments can be devised that do not depart from the scope of the invention as disclosed herein. Accordingly, the scope of the invention should be limited only by the attached claims.

What is claimed is:

1. A sensor plate, comprising:
a top surface;
at least one mounting tab; and
at least one leg disposed between the top surface and the at least one mounting tab, wherein the at least one leg is non-linear.

2. The sensor plate of claim 1 wherein the top surface, the at least one mounting tab, and the at least one leg are formed as a one-piece conductive member.

3. A proximity sensor, comprising:
an interface board; and
a sensor plate operatively connected to the interface board.

4. A module comprising:
at least one external member; and
a proximity sensor disposed within the at least one external member.

5. The module of claim 4, wherein the at least one external member forms an explosion-proof housing.

6. The module of claim 4, wherein the proximity sensor comprises a sensor plate operatively connected to an interface board.

7. The module of claim 4, wherein the at least one external member includes a transparent member.

8. The module of claim 7, wherein a sensor plate of the proximity sensor is proximate the transparent member.

9. The module of claim 7, wherein the sensor plate of the proximity sensor is compressed by the transparent member.

10. The module of claim 4, wherein a second proximity sensor is disposed within the at least one external member.

11. The module of claim 4, wherein at the at least one external member includes at least one interface.

12. The module of claim 4 further comprising a display disposed within the at least one external member.

13. The module of claim 12, wherein the interface board includes a window.

14. The module of claim 12, wherein the interface board includes a display.

15. A method of assembling a proximity sensor, comprising:
constructing a sensor plate; and
operatively connecting the sensor plate to an interface board.

16. The method of claim 15, wherein the constructing a sensor plate further comprises forming a conductive member into at least one leg, at least one mounting pad and a top surface.

17. The method of claim 16, wherein the forming further comprises bending the top surface to form a non-planar surface.

18. A method of compressing a sensor plate of a proximity sensor, comprising:
installing the proximity sensor in a housing; and
manipulating a first external member of the housing to compress the sensor plate.

19. The method of claim 18, wherein the manipulating further comprises attaching the first external member to a second external member using threads.

20. The method of claim 18, wherein the installing further comprises operatively connecting the proximity sensor to electrical components.

21. A module comprising:
at least one external member; and
a proximity sensor disposed within the at least one external member, wherein the proximity sensor comprises a plurality of sensor plates operatively connected to an interface board.

22. A module comprising:
at least one external member; and
a plurality of proximity sensors.
